(19) United States
(12) Patent Application Publication
(10) Pub. No.: US 2018/0259555 A1
(43) Pub. Date: Sep. 13, 2018

(54) PROBER AND METHOD FOR POSITIONING PROBE TIP AND OBTAINING PROBE AND POLISHING SHEET CONTACT DATA

(71) Applicant: WIN Semiconductors Corp., Taoyuan City (TW)

(72) Inventors: Shu-Jeng YEH, Taoyuan City (TW); Fancy FANG, Taoyuan City (TW); Ju-Cheng YU, Taoyuan City (TW)

(21) Appl. No.: 15/498,270

(22) Filed: Apr. 26, 2017

(30) Foreign Application Priority Data
Mar. 10, 2017 (TW) 106108052

(51) Int. Cl. G01R 3/00; G01R 1/04; G01R 1/073; G01L 1/00

(52) U.S. Cl. CPC G01R 3/00; G01L 1/005; G01R 1/07307; G01R 1/04

(57) ABSTRACT

A prober and methods using the prober for positioning a probe tip and for obtaining contact data of a probe and a polishing sheet. The prober comprises a probe card holder for holding a probe card having at least one probe, and each of the at least one probe having a probe tip; a force sensor, provided below the probe card holder, and having a sensing surface for being in contact with the probe tip; and at least one moving device, for moving the force sensor and the probe relatively in the direction toward each other, wherein, as the probe tip being in contact with the sensing surface, the force sensor sensing a force and producing a signal, so as to stop moving the force sensor and the probe relatively.

### FIELD OF THE INVENTION

The present invention relates to a prober and a positioning method thereof, and more particular to a prober and a method for positioning a probe tip by means of a force sensor sensing the contact of a probe, and to obtain contact data of a probe and a polishing sheet.

### BACKGROUND OF THE INVENTION

In the semiconductor manufacturing process, a manufactured semiconductor wafers must subject to electrical test in a prober. During wafer testing, as the probe contact the wafer, the probe may scrub debris from the wafer. The debris are accumulated and remained on the probe after many times of contact and the performance of the probe is reduced, which results in a reduced wafer test yield rate. Therefore, the probe must be polished and cleaned regularly to maintain the quality of wafer test. Cleaning of probe is performed by the probe cleaning device in the prober. Whether the probe cleaning device is able to clean the probe properly will directly response in the testing quality and the yield rate, and it also effects the testing time and the duration of the probe. Therefore, it is an important issue in wafer testing process to reach the optimum cleaning efficiency of the probe cleaning device of the prober. The critical parameters for optimizing the efficiency of the probe cleaning device are the probe cleaning frequency and depth, in which the setting of the probe cleaning position in the z-axis (i.e. the vertical direction) determines if the probe cleaning depth is effective for probe cleaning and does not damage the probe. A proper setting of the z-axis probe cleaning position requires precisely positioning the z-axis position of the probe tip.

The probe cleaning devices of some of the commercially available probers are equipped with probe position detecting systems, such as an air nozzle feedback conversion voltage system and an image recognition autofocus system. But some of the commercially available probers are not equipped with probe position detecting systems. The z-axis probe cleaning position in a prober without a probe position detecting system is usually determined manually with eye estimation through a microscope. However, without the corroboration of objective data, the probe cleaning problem due to inadequate or too deep probe cleaning depth occurs frequently by using the eye estimation method. An inadequate probe cleaning depth indicates that the set-up z-axis probe cleaning position is too low, which leads to insufficient probe cleaning and lower the test yield rate, and the yield of the production line is lowered due to the prolonged testing time resulting from re-test. A too deep probe cleaning depth indicates that the set-up z-axis probe cleaning position is too high, which, depending on the properties of the polishing sheet, may lead to insufficient probe cleaning and lower the test yield rate or lead to over-contact of the probe and the polishing sheet and reduce the duration of the probe. A too high z-axis probe cleaning position may lead to probe kneeling or scrap problems. If a damaged probe is not observed and removed right away, the testing wafer may be damaged and scraped, which results to reduced yield rate. Moreover, the probe tip position may be changed due to the abrasion of probe or probe card replacement. Therefore, the proper z-axis probe cleaning position must be detected and reset each time when replacing the probe card. The conventional manual setting method with eye estimation is time consuming and reduces the wafer test efficiency.

### SUMMARY OF THE INVENTION

Accordingly, in order to solve the foregoing problem, the present invention provides a prober and a probe tip positioning method, and further provides a method for obtaining contact data of a probe and a polishing sheet, which can improve the precision of probe tip positioning and provide contact data of a probe and a polishing sheet to help to determine a proper z-axis probe cleaning position, thereby improving the wafer test yield rate and reducing the time needed for resetting the z-axis probe cleaning position. Moreover, the present invention can be applied to the currently available probers easily.

To reach the objects stated above, the present invention provides a probe tip positioning method for positioning a probe tip of a probe in a prober, wherein the prober comprises a force sensor, and the force sensor has a sensing surface. The method comprises steps of:

A1. moving the force sensor and the probe relatively in the direction toward each other by at least one moving device, so that the sensing surface being in contact with the probe tip; and

A2. as the probe tip being in contact with the sensing surface, stopping moving the force sensor and the probe relatively and obtaining the positions of the force sensor and the probe.

In implementation, a polishing sheet may be provided on the sensing surface of the force sensor for being in contact with the probe tip.

In implementation, the step A2 may comprise: as the probe tip being in contact with the sensing surface, the force sensor sensing a force and producing a signal, stopping moving the force sensor and the probe relatively by a user according to the signal and obtaining the positions of the force sensor and the probe.

In implementation, the step A2 may comprise: as the probe tip being in contact with the sensing surface, the force sensor sensing a force and producing a signal, converting the signal to a signal value, stopping moving the force sensor and the probe relatively by a user according to the signal value and obtaining the positions of the force sensor and the probe.

In implementation, the step A2 may comprise: as the probe tip being in contact with the sensing surface, the force sensor sensing a force and producing a signal, stopping moving the force sensor and the probe relatively by the signal and obtaining the positions of the force sensor and the probe.

In implementation, the at least one moving device may move at least one of the force sensor and the probe.

The present invention further provides a method for obtaining contact data of a probe and a polishing sheet, wherein the probe has a probe tip and the polishing sheet is provided on a force sensor. The method comprises steps of:

B1. moving the force sensor and the probe relatively in the direction toward each other by at least one moving device;

B2. as the probe tip being in contact with the polishing sheet provided on the force sensor, the force sensor sensing different forces and producing plural of signals, converting the plural signals to plural corresponding signal values;

B3. obtaining a distance between the force sensor and the probe corresponding to each of the plural signals; and

B4. based on the obtained plural signal values corresponding to the plural signals and distance corresponding to the plural signals, obtaining a relation between the distance and the signal values.

Moreover, the present invention provides a prober, comprising: a probe card holder for holding a probe card having at least one probe, and each of the at least one probe having a probe tip; a force sensor, provided below the probe card holder, and having a sensing surface for being in contact with the probe tip; and at least one moving device, for moving the force sensor and the probe relatively in the direction toward each other, wherein, as the probe tip being in contact with the sensing surface, the force sensor sensing a force and producing a signal, so as to stop moving the force sensor and the probe relatively.

In implementation, the prober may further comprise a polishing sheet provided on the sensing surface of the force sensor for being in contact with the probe tip.

In implementation, the at least one moving device of the prober may move at least one of the force sensor and the probe.

In implementation, the force sensor is a load sensor.

In implementation, the force sensor is a parallel beam load cell.

In implementation, the signal may be an electric voltage signal or an electric current signal.

The present invention will be understood more fully by reference to the detailed description of the drawings and the preferred embodiments below.

### BRIEF DESCRIPTION OF DRAWINGS

FIG. 1 is a schematic view showing an embodiment of a prober provided by the present invention.

FIG. 2 is a schematic view showing an embodiment of a probe cleaning device in a prober provided by the present invention.

FIG. 3 is a flow chart of an embodiment of a probe tip positioning method provided by the present invention.

FIG. 4 is a flow chart of an embodiment of a method for obtaining contact data of a probe and a polishing sheet provided by the present invention.

FIG. 5 is a graph of the relation of the distance between the force sensor and the probe and the signal value of the force sensor measured in an embodiment of a method for obtaining contact data of a probe and a polishing sheet provided by the present invention.

### DETAILED DESCRIPTIONS OF PREFERRED EMBODIMENTS

The present invention provides a prober, comprising: a probe card holder for holding a probe card having at least one probe, and each of the at least one probe having a probe tip; a force sensor, provided below the probe card holder, and having a sensing surface for being in contact with the probe tip; and at least one moving device, for moving the force sensor and the probe relatively in the direction toward each other, wherein, as the probe tip being in contact with the sensing surface, the force sensor sensing a force and producing a signal, so as to stop moving the force sensor and the probe relatively.

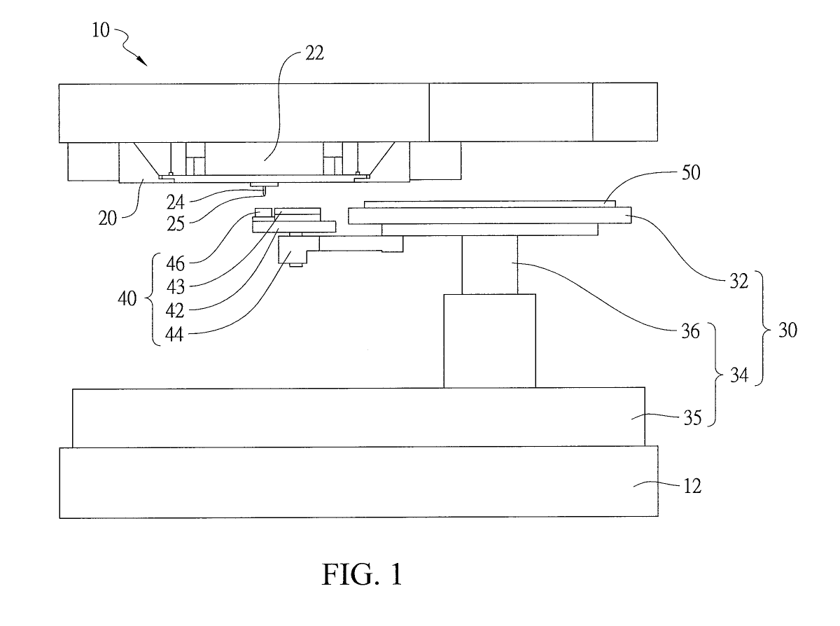

FIG. 1 shows an embodiment of a prober provided by the present invention. The prober 10 comprises: a probe card holder 20, a testing module 30, and a probe cleaning device 40. The probe card holder 20 is for holding a probe card 22 having at least one probe 24. The testing module 30 is provided below the probe card holder 20 and comprises a wafer chuck 32 and a moving device 34. The wafer chuck 32 is provided on the moving device 34 for mounting a wafer 50. The moving device 34 is used to move the wafer chuck 32. The probe cleaning device 40 is provided below the probe card holder 20 and is connected to the wafer chuck 32 with a support 44. The probe cleaning device 40 comprises a probe cleaning plate 42, and a polishing sheet 43 and a force sensor 46 are provided on the probe cleaning plate 42.

The embodiment shown in FIG. 1 may comprise a base 12. The moving device 34 is provided on the base 12 and comprises a horizontal moving mechanism 35 and a vertical moving mechanism 36. The horizontal moving mechanism 35 may horizontally displace the wafer chuck on the base 12, and the vertical moving mechanism 36 may vertically lift the wafer chuck 32 up and down on the horizontal moving mechanism 35. The horizontal moving mechanism 35 and the vertical moving mechanism 36 may move the wafer chuck 32 in a stepwise manner. In a wafer test process, the wafer chuck 32 is first displaced by the horizontal moving mechanism 35 to a position right below the probe 24 and then lifted up stepwise until it is in contact with a probe tip 25 of the probe 24, and a wafer test is then performed. In a probe cleaning process, the probe cleaning device 40 is first displaced by the horizontal moving mechanism 35 till the polishing sheet 43 is right below the probe 24 and then lifted up stepwise until the polishing sheet 43 is in contact with a probe tip 25 of the probe 24, and a probe cleaning process is then performed.

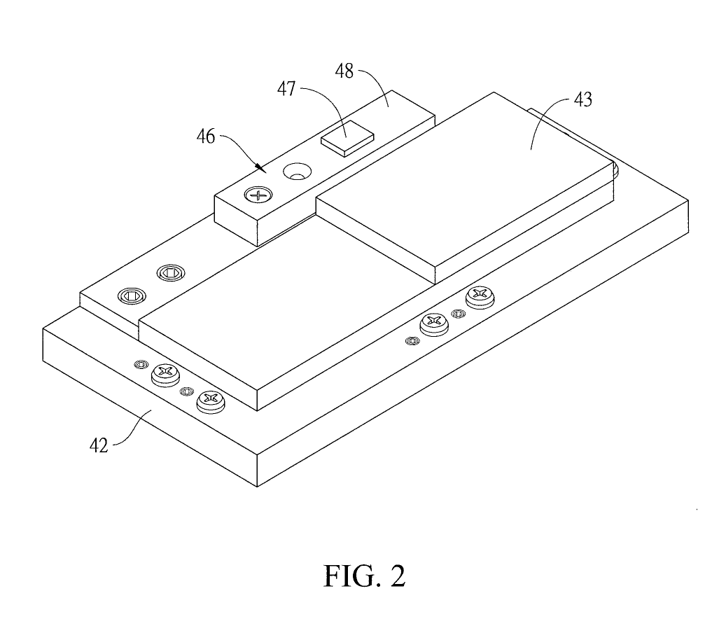

In the probe cleaning process, in order to properly clean the probe without damaging the probe, the position of the probe tip must be precisely positioned, particularly the vertical position of the probe tip. The present invention provides a scheme to determine the vertical position of the probe tip with the assistance of a force sensor. In one embodiment, the force sensor may be provided on the probe cleaning device. As shown in FIG. 2, the force sensor 46 has a sensing surface 48. The force sensor 46 is provided beside the polishing sheet 43 on the probe cleaning device 40 with its sensing surface 48 facing upward. When positioning the position of the probe tip 25, the force sensor 46 is first horizontally displaced to a position right below the probe 24 and then lifted up stepwise. As the probe tip 25 is in contact with the sensing surface 48, the force sensor 46 sensing a force and producing a signal. Stop lifting the force sensor 46 at the meantime and obtain the vertical position of the force sensor 46, and define the position of the probe tip 25 accordingly. In one embodiment, another polishing sheet 47 may be provided on the sensing surface 48 of the force sensor 46. The probe tip 25 may be in contact with the polishing sheet 47 when positioning the position of the probe tip 25 to prevent damaging the probe.

In one embodiment, the force sensor 46 may be a load sensor, preferably a parallel beam load cell. A parallel beam load cell has the advantages of high precision, easy processing, structural compactness, high anti-bias load capacity, high frequency, and can be incorporated into the prober provided by the present invention by simple processing, and it may be obtained from a variety of commercial scales, such as a digital lab scale, a digital postal scale, a digital kitchen scale, a digital spoon scale, etc.

In the abovementioned embodiment, the probe is fixed in the prober, and the force sensor is moved approaching the probe for positioning the probe tip by the moving device. In one embodiment, the force sensor may be fixed in the prober instead, and the probe is moved approaching the force sensor for positioning the probe tip by the moving device. In another embodiment, the moving device may move the probe and the force sensor simultaneously in the direction approaching each other. When the probe tip is in contact with the sensing surface of the force sensor resulting in a signal production, stop moving the probe and the force sensor and obtain the positions of the probe and the force sensor in reference to the prober. The moving device provided by the present invention may include a variety of moving mechanism. In one embodiment, the moving device is a manipulator that can displace at least one of the probe and the force sensor in all direction.

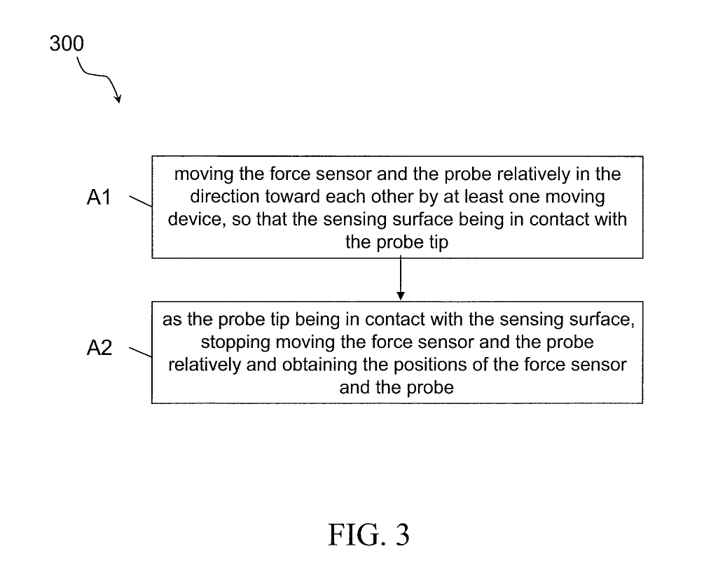

The present invention also provides a probe tip positioning method 300 for positioning a probe tip of a probe in a prober, wherein the prober comprises a force sensor, and the force sensor has a sensing surface. As shown in FIG. 3, the method 300 comprises steps of:

A1. moving the force sensor and the probe relatively in the direction toward each other by at least one moving device, so that the sensing surface being in contact with the probe tip; and

A2. as the probe tip being in contact with the sensing surface, stopping moving the force sensor and the probe relatively and obtaining the positions of the force sensor and the probe.

In one embodiment, the step A2 may comprise: as the probe tip being in contact with the sensing surface, the force sensor sensing a force and producing a signal, stopping moving the force sensor and the probe relatively by a user according to the signal and obtaining the positions of the force sensor and the probe.

In one embodiment, the step A2 may comprise: as the probe tip being in contact with the sensing surface, the force sensor sensing a force and producing a signal, converting the signal to a signal value, stopping moving the force sensor and the probe relatively by a user according to the signal value and obtaining the positions of the force sensor and the probe.

In one embodiment, the step A2 may comprise: as the probe tip being in contact with the sensing surface, the force sensor sensing a force and producing a signal, stopping moving the force sensor and the probe relatively by the signal and obtaining the positions of the force sensor and the probe.

In one embodiment, in order to prevent damaging the probe, a polishing sheet may be provided on the sensing surface of the force sensor for being in contact with the probe tip.

In one embodiment, the force sensor may be a load sensor, preferably a parallel beam load cell. A parallel beam load cell may be obtained from a variety of commercial scales, such as a digital lab scale, a digital postal scale, a digital kitchen scale, a digital spoon scale, etc.

In one embodiment, the signal may be an electric voltage signal or an electric current signal. In one embodiment, the electric voltage signal or an electric current signal produced by the force sensor may trigger a control device to stop moving the probe and the force sensor relatively by the moving device. The force sensor may comprise a conversion device for converting the signal produced by the force sensor to a signal value.

In one embodiment, the moving device may move the probe and the force sensor relatively in a stepwise manner. In one embodiment, the moving device may move one of the probe and the force sensor, or the moving device may simultaneously move the probe and the force sensor, as long as the positions of the probe and the force sensor reference to the prober can be obtained. In one embodiment, the moving device may comprise a horizontal moving mechanism and a vertical moving mechanism. In one embodiment, the moving device is a manipulator that can displace at least one of the probe and the force sensor in all direction.

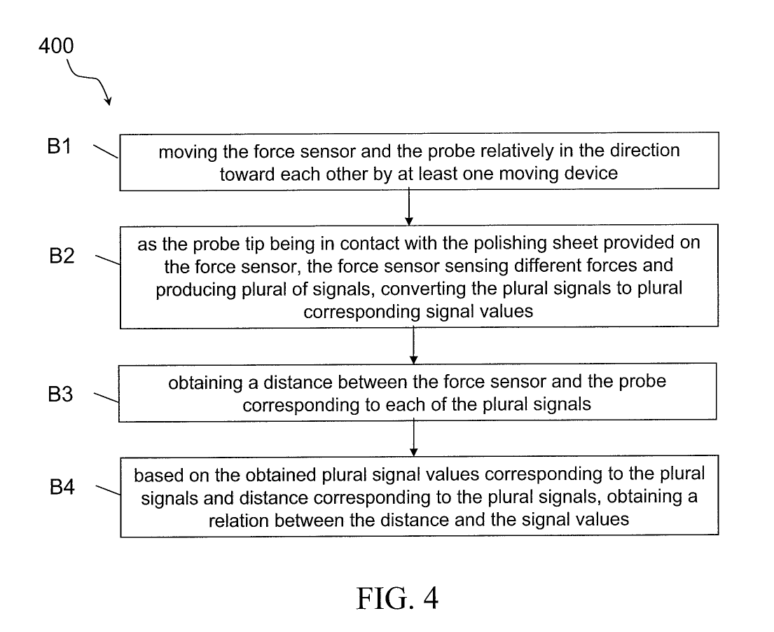

Moreover, the present invention provides a method 400 for obtaining contact data of a probe and a polishing sheet, wherein the probe has a probe tip and the polishing sheet is provided on a force sensor. As shown in FIG. 4, the method 400 comprises:

B1. moving the force sensor and the probe relatively in the direction toward each other by at least one moving device;

B2. as the probe tip being in contact with the polishing sheet provided on the force sensor, the force sensor sensing different forces and producing plural of signals, converting the plural signals to plural corresponding signal values;

B3. obtaining a distance between the force sensor and the probe corresponding to each of the plural signals; and

B4. based on the obtained plural signal values corresponding to the plural signals and distance corresponding to the plural signals, obtaining a relation between the distance and the signal values.

In one embodiment, the force sensor may be a load sensor, preferably a parallel beam load cell. A parallel beam load cell may be obtained from a variety of commercial scales, such as a digital lab scale, a digital postal scale, a digital kitchen scale, a digital spoon scale, etc.

In one embodiment, the signal may be an electric voltage signal or an electric current signal.

In one embodiment, the moving device may move the probe and the force sensor relatively in a stepwise manner. In one embodiment, the moving device may move one of the probe and the force sensor, or the moving device may simultaneously move the probe and the force sensor, as long as the positions of the probe and the force sensor reference to the prober can be obtained. In one embodiment, the moving device may comprise a horizontal moving mechanism and a vertical moving mechanism. In one embodiment, the moving device is a manipulator that can displace at least one of the probe and the force sensor in all direction.

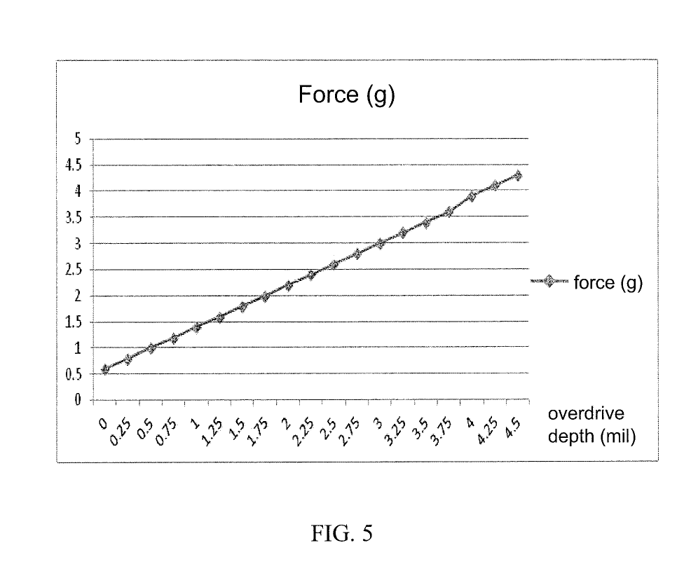

In implementation, the force sensor usually has a minimum threshold. The force sensor must bear a force larger than the threshold to produce detectable signal. FIG. 5 shows a graph of the relation of the distance between the force sensor and the probe and the signal value of the force sensor measured in an embodiment of the method 400. In the embodiment, the force sensor is a parallel beam load cell with a minimum threshold of 0.6 gram. The distance between the force sensor and the probe is represented by the depth (mil) of a probe overdrive, i.e. the contact depth of the probe and the polishing sheet. The signal value produced by the force sensor is represented by the value of the applied force (gram). When the force sensor sensing a force of 0.6 gram, the probe tip is determined as being in contact with the polishing sheet on the force sensor, and the overdrive depth is defined as zero. Lift the force sensor up stepwise with a step of 0.25 mil. As shown in the figure, the value of the applied force on the force sensor is increased substantially linearly with increasing overdrive depth of the probe. The force detected by the force sensor is increased by 0.2 gram with the overdrive depth increased by every 0.25 mil. When performing a probe cleaning process, the optimum position for probe cleaning can be determined according to the contact data of a probe and a polishing sheet measured by using the method 400.

According to the wafer test yield rate data obtained under the same testing conditions, the wafer test yield rate is about 30% with the probe cleaning setting determined by using a conventional eye estimation by a tester, and the wafer test yield rate is about 90% with the probe cleaning setting determined by using the methods provided by the present invention. The wafer test yield rate is obviously improved by using the methods provided by the present invention.

Accordingly, the present invention has the following advantages:

1. The prober and the probe tip positioning method provided by the present invention can improve the precision of probe tip positioning. Therefore, the performance of probe cleaning device can be improved, and the probe can be cleaned properly, leading to an improved wafer test yield rate.

2. Due to the abrasion of probe or probe card replacement, the proper z-axis probe cleaning position must be detected and reset regularly. The prober and the probe tip positioning method provided by the present invention can reduce the time needed for each resetting the z-axis probe cleaning position and hence improving the wafer test efficiency.

3. The prober and the probe tip positioning method provided by the present invention can provide contact data of a probe and a polishing sheet to help to determine a proper z-axis probe cleaning position, so that the probe kneeling or scrap problems due to over-contact of the probe and the polishing sheet can be prevented, therefore avoiding wafer damaging or scrap.

4. The prober and the probe tip positioning method provided by the present invention are to provide a force sensor on the currently available prober to help to position the position of the probe tip. The force sensor used in the present invention is easily available and inexpensive, and the scheme is simple and can be incorporated into the currently available prober easily.

To sum up, the prober and the probe tip positioning method provided by the present invention can indeed meet its anticipated objective to improve the precision of probe tip positioning and provide contact data of a probe and a polishing sheet to help to determine a proper z-axis probe cleaning position. The prober and the method provided by the present invention can improve the wafer test yield rate and reduce the time needed for resetting the z-axis probe cleaning position, and they can be applied to the currently available probers easily.

The description referred to in the drawings and stated above is only for the preferred embodiments of the present invention. Many equivalent local variations and modifications can still be made by those skilled at the field related with the present invention and do not depart from the spirit of the present invention, so they should be regarded to fall into the scope defined by the appended claims.

1. A probe tip positioning method for positioning a probe tip of a probe in a prober, wherein the prober comprises a force sensor, and the force sensor has a sensing surface, the method comprising steps of:
A1. moving the force sensor and the probe relatively in the direction toward each other by at least one moving device, so that the sensing surface being in contact with the probe tip; and
A2. as the probe tip being in contact with the sensing surface, stopping moving the force sensor and the probe relatively and obtaining the positions of the force sensor and the probe.

2. The probe tip positioning method according to claim 1, further comprising a polishing sheet provided on the sensing surface of the force sensor for being in contact with the probe tip.

3. The probe tip positioning method according to claim 1, wherein the force sensor is a load sensor.

4. The probe tip positioning method according to claim 3, wherein the force sensor is a parallel beam load cell.

5. The probe tip positioning method according to claim 1, wherein the step A2 comprising: as the probe tip being in contact with the sensing surface, the force sensor sensing a force and producing a signal, stopping moving the force sensor and the probe relatively by a user according to the signal and obtaining the positions of the force sensor and the probe.

6. The probe tip positioning method according to claim 1, wherein the step A2 comprising: as the probe tip being in contact with the sensing surface, the force sensor sensing a force and producing a signal, converting the signal to a signal value, stopping moving the force sensor and the probe relatively by a user according to the signal value and obtaining the positions of the force sensor and the probe.

7. The probe tip positioning method according to claim 1, wherein the step A2 comprising: as the probe tip being in contact with the sensing surface, the force sensor sensing a force and producing a signal, stopping moving the force sensor and the probe relatively by the signal and obtaining the positions of the force sensor and the probe.

8. The probe tip positioning method according to claim 1, wherein the at least one moving device moves at least one of the force sensor and the probe.

9. The probe tip positioning method according to claim 5, wherein the signal is an electric voltage signal or an electric current signal.

10. A method for obtaining contact data of a probe and a polishing sheet, wherein the probe has a probe tip and the polishing sheet is provided on a force sensor, the method comprising steps of:
B1. moving the force sensor and the probe relatively in the direction toward each other by at least one moving device;
B2. as the probe tip being in contact with the polishing sheet provided on the force sensor, the force sensor sensing different forces and producing plural of signals, converting the plural signals to plural corresponding signal values;
B3. obtaining a distance between the force sensor and the probe corresponding to each of the plural signals; and
B4. based on the obtained plural signal values corresponding to the plural signals and distance corresponding to the plural signals, obtaining a relation between the distance and the signal values.

11. The method for obtaining contact data of a probe and a polishing sheet according to claim 10, wherein the force sensor is a load sensor.

12. The method for obtaining contact data of a probe and a polishing sheet according to claim 11, wherein the force sensor is a parallel beam load cell.

13. The method for obtaining contact data of a probe and a polishing sheet according to claim 10, wherein the signal is an electric voltage signal or an electric current signal.

14. A prober, comprising:
a probe card holder for holding a probe card having at least one probe, and each of the at least one probe having a probe tip;
a force sensor, provided below the probe card holder, and having a sensing surface for being in contact with the probe tip; and
at least one moving device, for moving the force sensor and the probe relatively in the direction toward each other,
wherein, as the probe tip being in contact with the sensing surface, the force sensor sensing a force and producing a signal, so as to stop moving the force sensor and the probe relatively.

15. The prober according to claim 14, further comprising a polishing sheet provided on the sensing surface of the force sensor for being in contact with the probe tip.

16. The prober according to claim 14, wherein the force sensor is a load sensor.

17. The prober according to claim 16, wherein the force sensor is a parallel beam load cell.

18. The prober according to claim 16, wherein the at least one moving device moves at least one of the force sensor and the probe.

19. The probe tip positioning method according to claim 6, wherein the signal is an electric voltage signal or an electric current signal.

20. The probe tip positioning method according to claim 7, wherein the signal is an electric voltage signal or an electric current signal.
